(19) United States
(12) Patent Application Publication
(10) Pub. No.: US 2025/0072031 A1
(43) Pub. Date: Feb. 27, 2025

(54) INTEGRATED CIRCUIT DEVICE AND METHOD FOR FABRICATING THE SAME

(71) Applicant: Taiwan Semiconductor Manufacturing Company, Ltd., Hsinchu (TW)

(72) Inventor: Jhon Jhy LIAW, Hsinchu County (TW)

(73) Assignee: Taiwan Semiconductor Manufacturing Company, Ltd., Hsinchu (TW)

(21) Appl. No.: 18/453,688

(22) Filed: Aug. 22, 2023

(51) Int. Cl. H01L 29/775; H01L 21/8238; H01L 21/84; H01L 27/12; H01L 29/06

(52) U.S. Cl. CPC H01L 29/775; H01L 21/82385; H01L 21/823864; H01L 21/823878; H01L 21/84; H01L 27/1207; H01L 29/0653; H01L 29/0673; H01L 29/42392

(57) ABSTRACT

An integrated circuit (IC) device includes a first nanostructure, a second nanostructure, a first gate structure, a first source/drain epitaxial structure, and a dielectric isolation layer. The first nanostructure is spaced apart from a semiconductor substrate by a first spacing. The second nanostructure is above and spaced apart from the first nanostructure by a second spacing less than the first spacing. The first gate structure surrounds the first nanostructure and the second nanostructure. The first source/drain epitaxial structure is adjacent to both the first nanostructure and the second nanostructure. The dielectric isolation layer is between the first source/drain epitaxial structure and the semiconductor substrate. A top surface of the dielectric isolation layer is higher than a top surface of the semiconductor substrate and lower than a bottom surface of the first nanostructure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8F illustrate layouts and cross-sectional views of an integrated circuit device at intermediate stages of fabrication process according to some embodiments of the present disclosure.

FIGS. 9A-9D are cross-sectional views of an integrated circuit device according to some embodiments of the present disclosure.

FIGS. 10A and 10B are cross-sectional views of an integrated circuit device according to some embodiments of the present disclosure.

FIGS. 11A and 11B are cross-sectional views of an integrated circuit device according to some embodiments of the present disclosure.

FIGS. 12A and 12B are cross-sectional views of an integrated circuit device according to some embodiments of the present disclosure.

FIGS. 13A and 13B are cross-sectional views of an integrated circuit device according to some embodiments of the present disclosure.

FIG. 14 is a cross-sectional view of an integrated circuit device according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

As with the other method embodiments and exemplary devices discussed herein, it is understood that parts of the integrated circuit device may be fabricated by a CMOS technology process flow, and thus some processes are only briefly described herein. Further, the exemplary integrated circuit structure may include various other devices and features, such as other types of devices such as additional transistors, bipolar junction transistors, resistors, capacitors, inductors, diodes, fuses, static random access memory (SRAM) and/or other logic circuits, etc., but is simplified for a better understanding of the concepts of the present disclosure. In some embodiments, the exemplary integrated circuit structure includes a plurality of semiconductor devices (e.g., transistors), including PFETs, NFETs, etc., which may be interconnected.

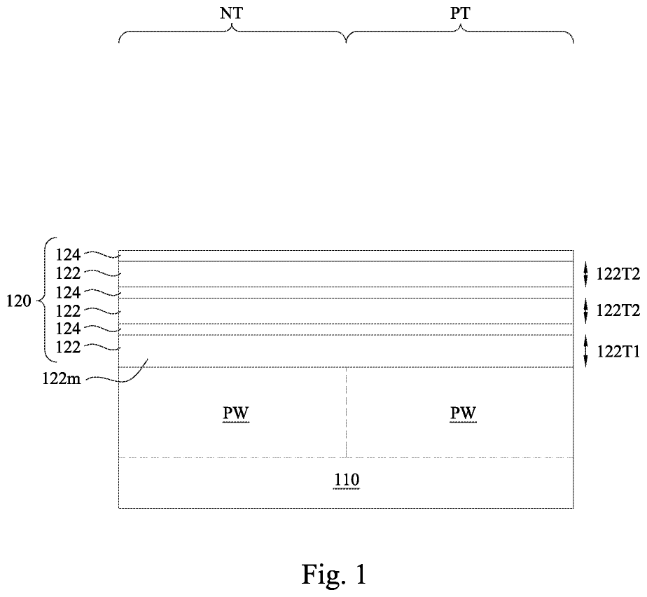

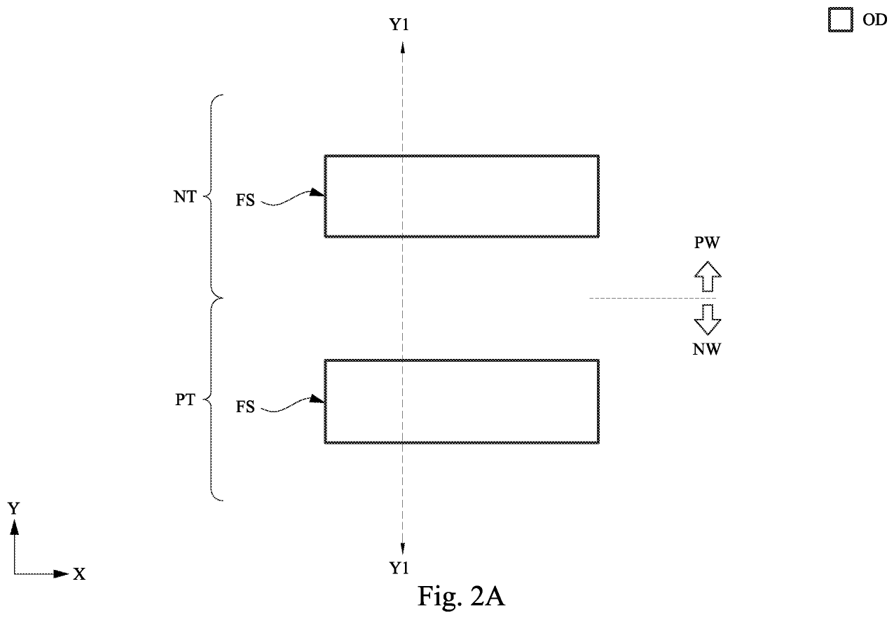

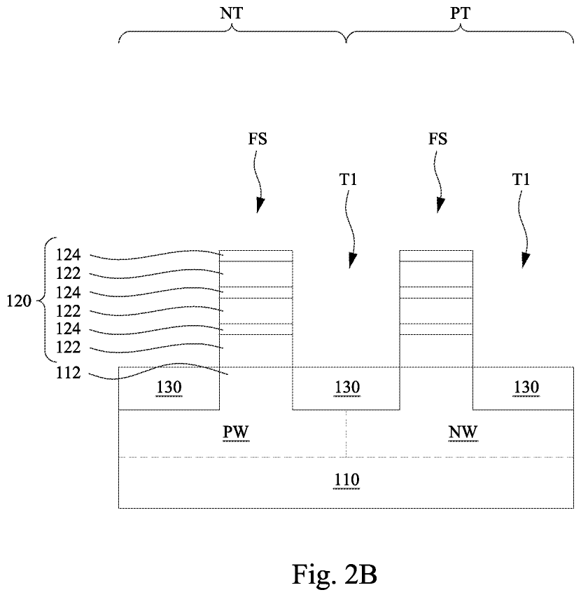

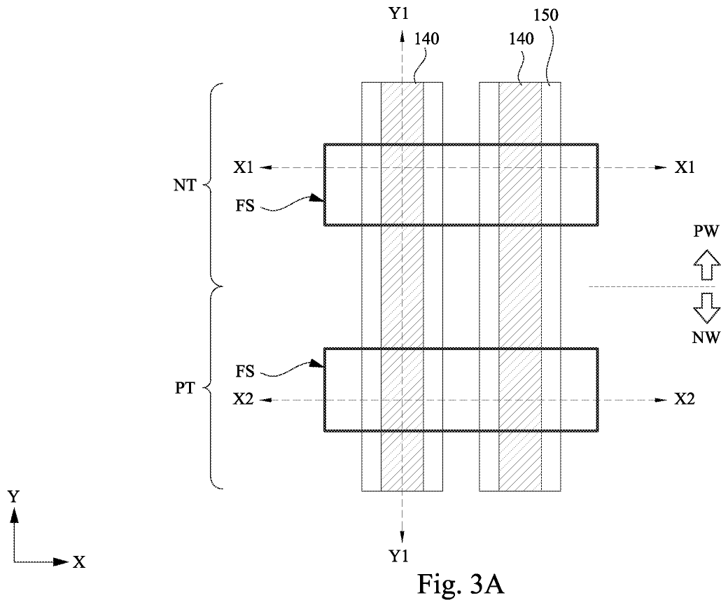

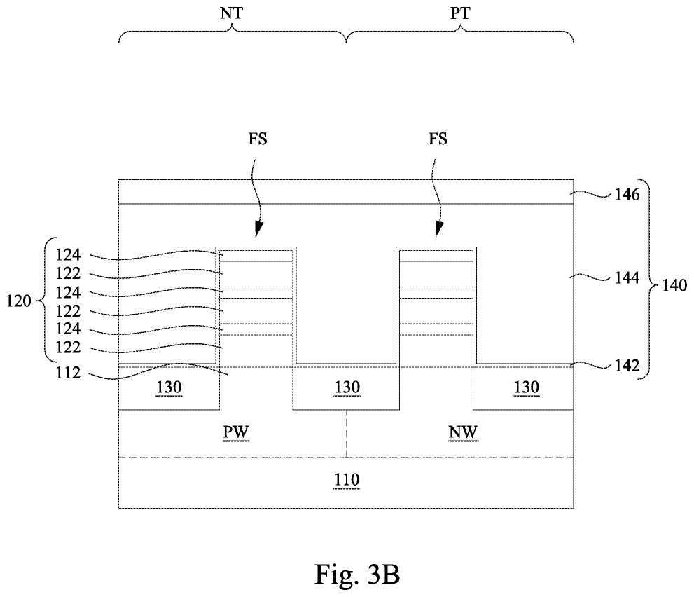

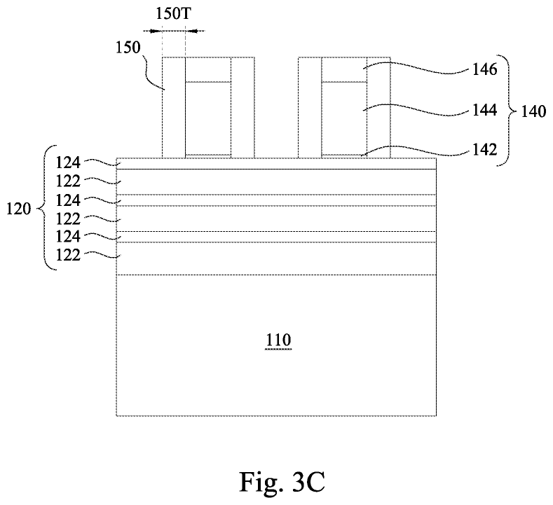

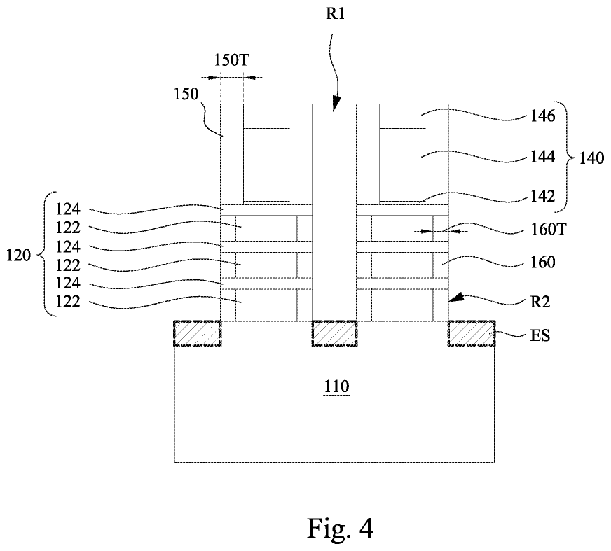

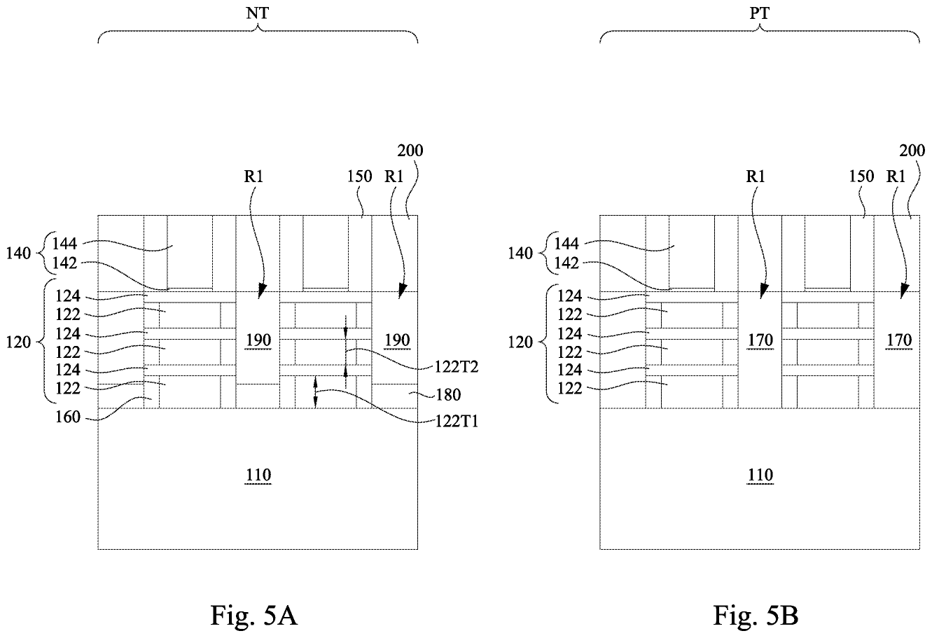

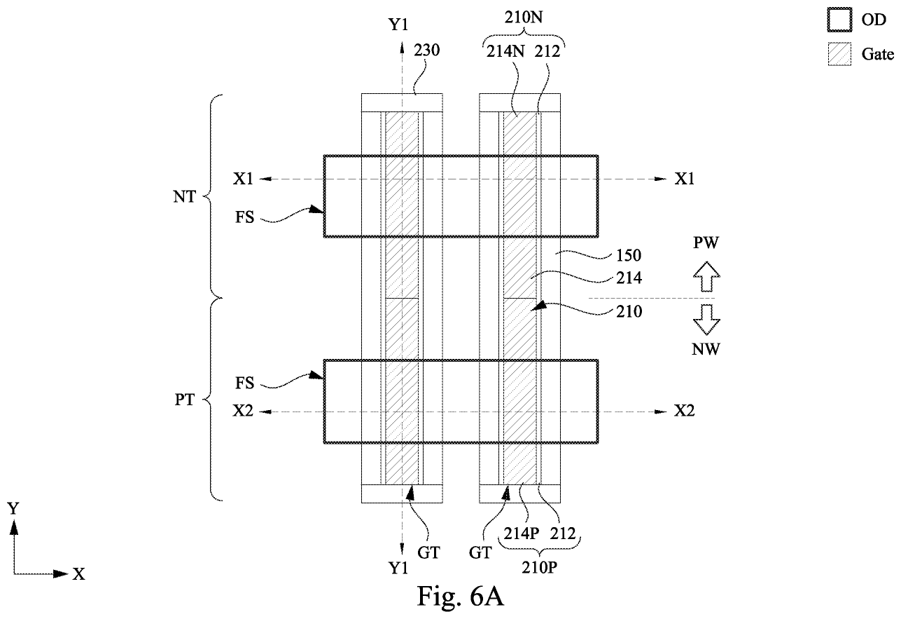

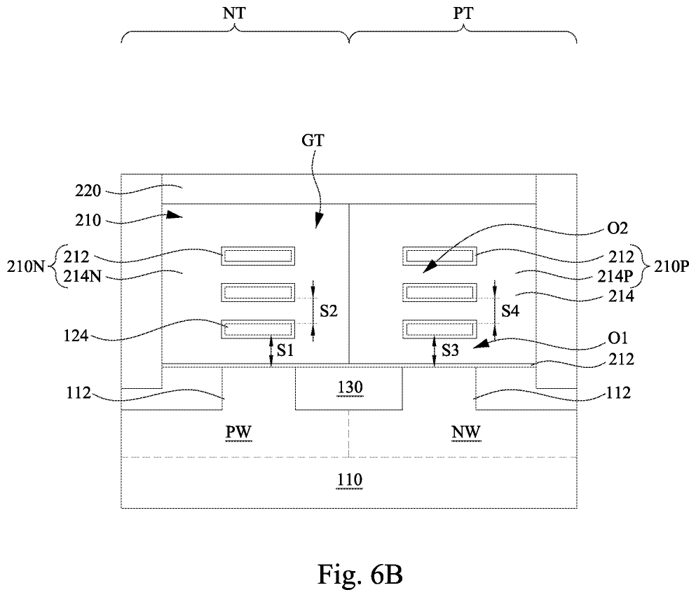

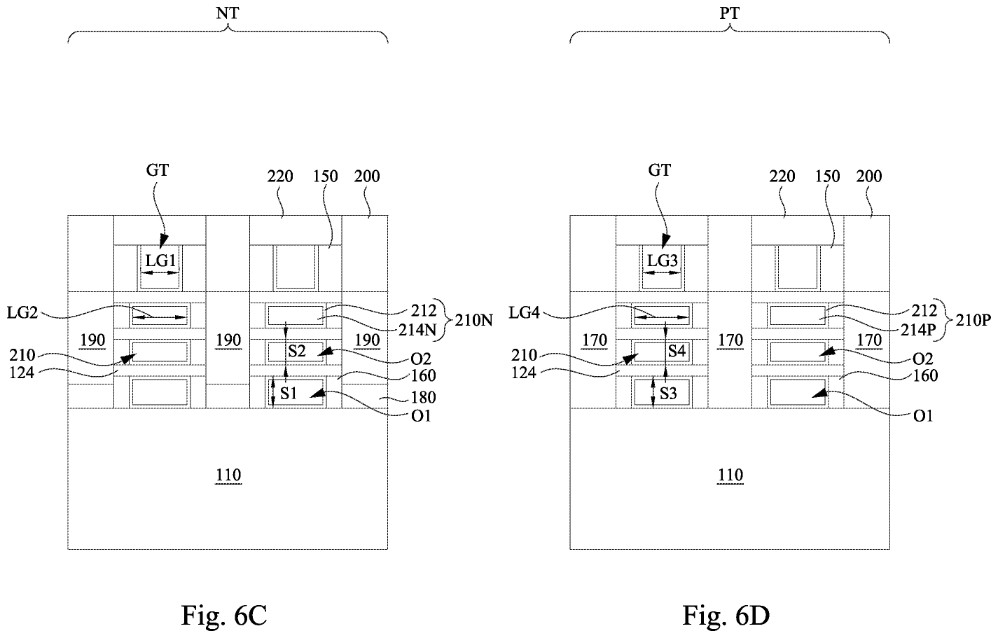

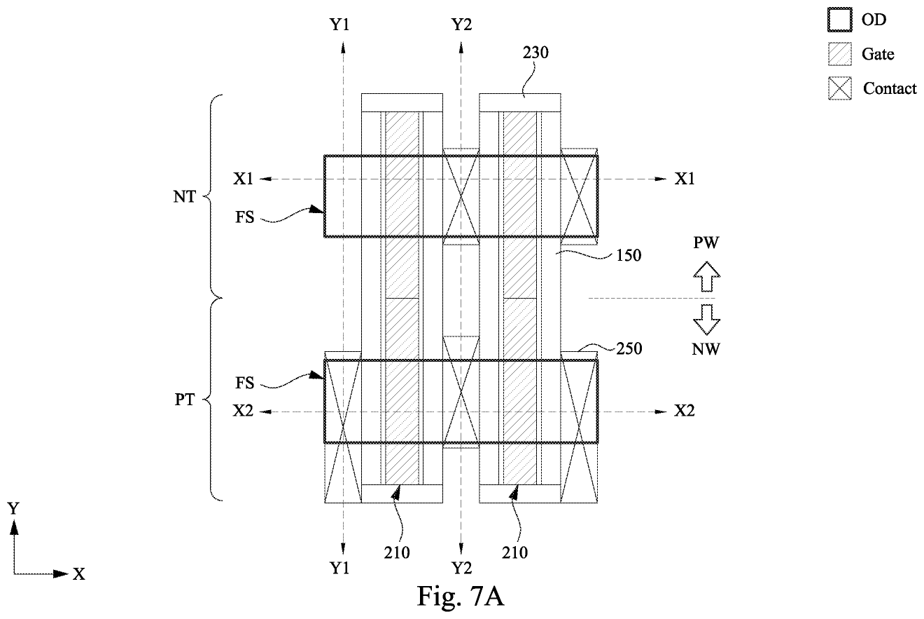

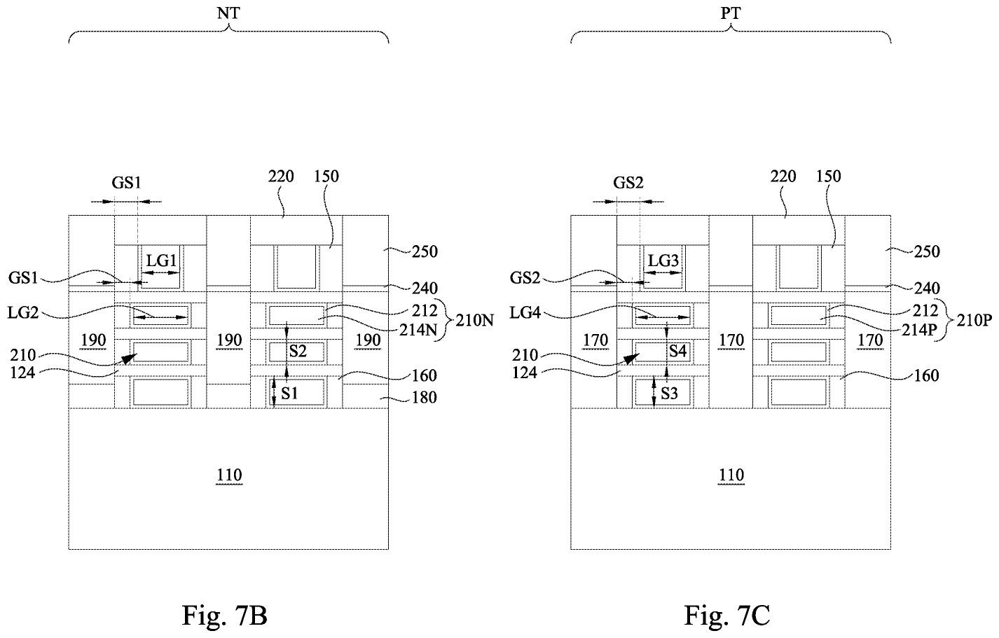

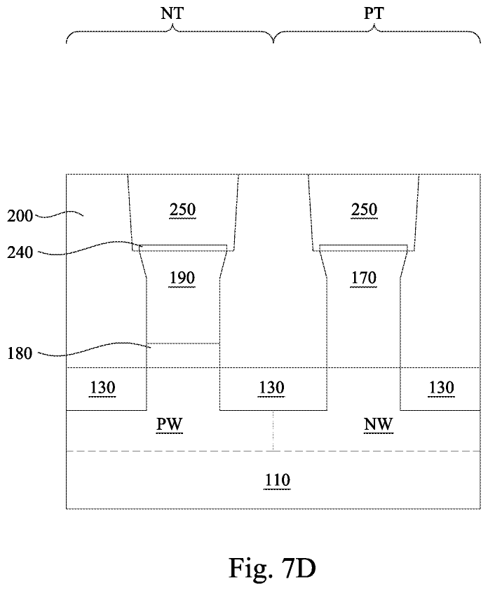

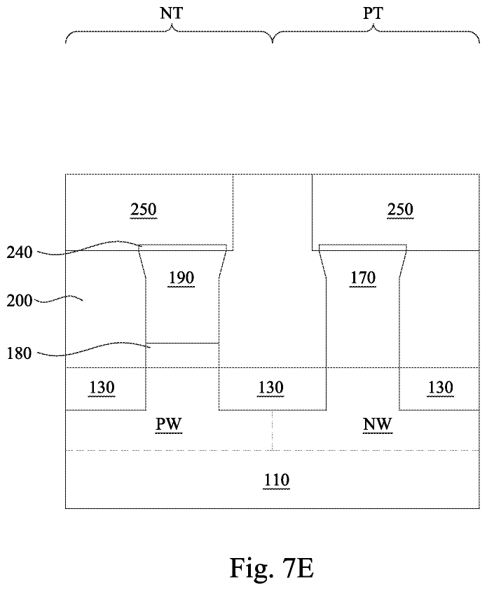

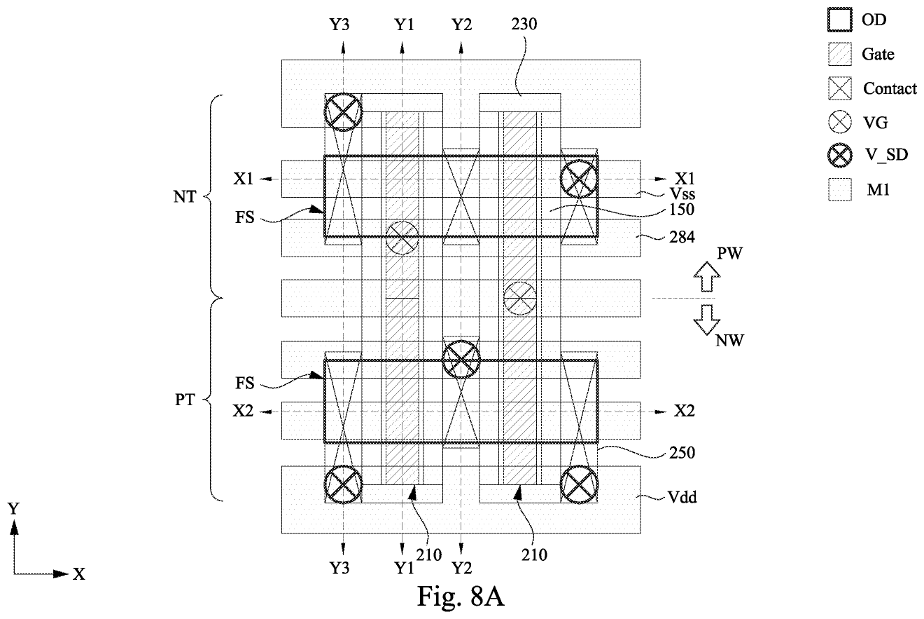

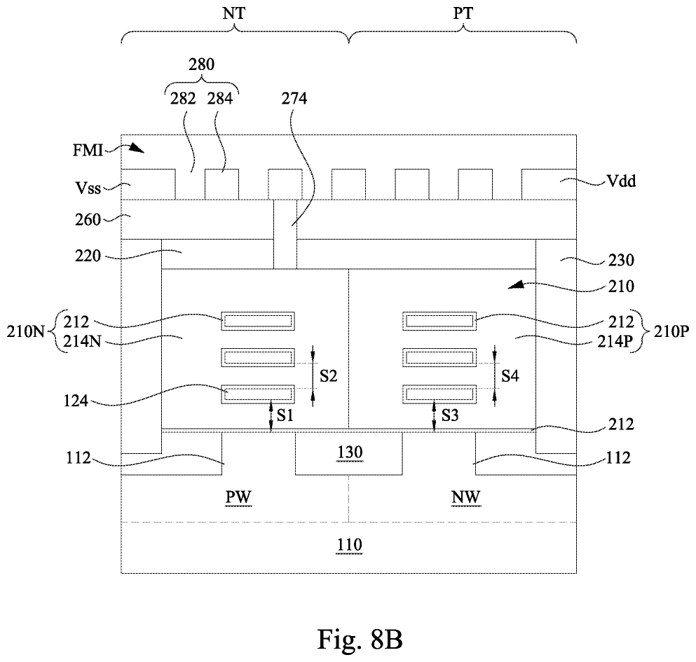

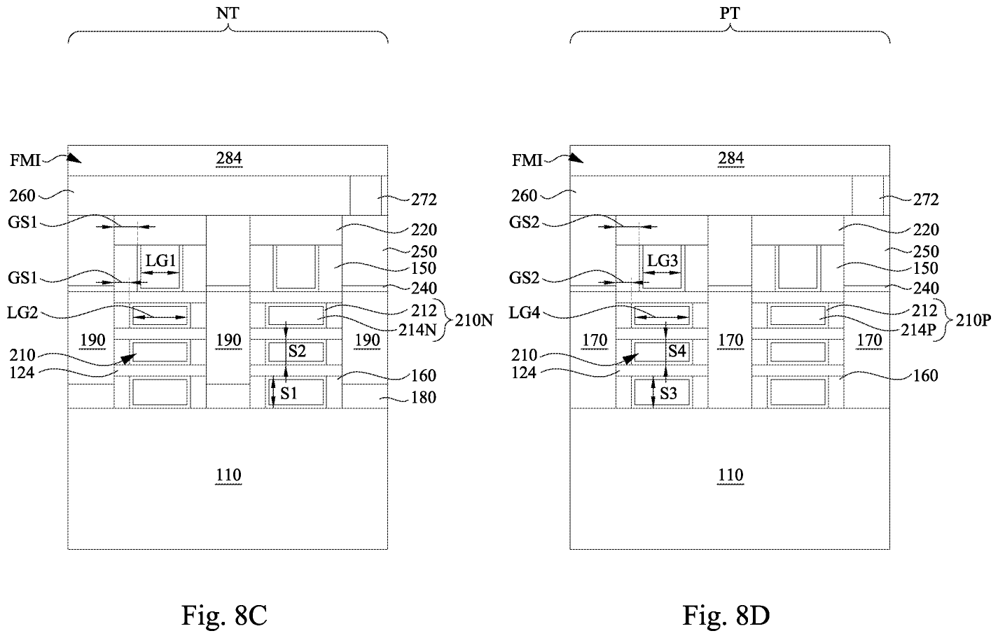

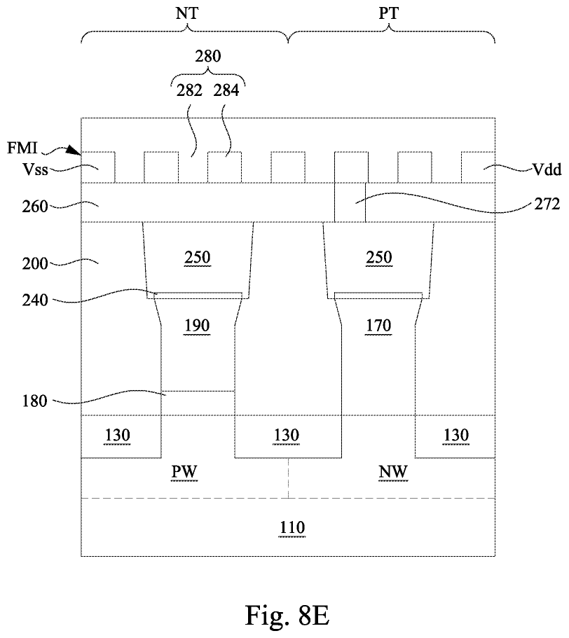

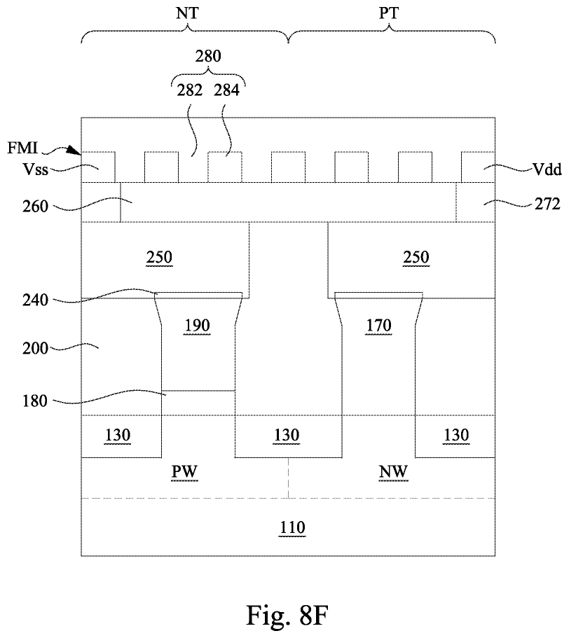

FIGS. 1-8F illustrate layouts and cross-sectional views of an integrated circuit device at intermediate stages of fabrication process according to some embodiments of the present disclosure. FIGS. 2A, 3A, 6A, 7A, and 8A are layouts of the integrated circuit structure at the intermediate stages of fabrication process according to some embodiments of the present disclosure. FIGS. 2B. 3B, 6B, and 8B illustrate cross-sectional views taken along line Y1-Y1 in FIGS. 2A, 3A, 6A, and 8A, respectively. FIG. 1 illustrates a cross-sectional view taken along the same line as the line Y1-Y1. FIGS. 3C, 6C, 7B, and 8C illustrate cross-sectional views taken along line X1-X1 in FIGS. 3A, 6A, 7A, and 8A, respectively. FIGS. 4 and 5A illustrate cross-sectional views taken along the same line as the line X1-X1. FIGS. 6D, 7C, and 8D illustrate cross-sectional views taken along line X2-X2 in FIGS. 6A, 7A, and 8A, respectively. FIG. 5B illustrates a cross-sectional view taken along the same line as the line X2-X2. FIGS. 7D and 8E illustrate cross-sectional views taken along line Y2-Y2 in FIGS. 7A and 8A, respectively. FIGS. 7E and 8F illustrate cross-sectional views taken along line Y3-Y3 in FIGS. 7A and 8A, respectively. It is understood that additional steps may be provided before, during, and after the steps shown in FIGS. 1-8F, and some of the steps described below can be replaced or eliminated for additional embodiments of the method. The order of the operations/processes may be interchangeable.

FIG. 1 shows an initial structure. The initial structure includes a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure. For example, the substrate 110 may include a bulk semiconductor substrate, a buried dielectric layer over the bulk substrate, and a semiconductor layer over the buried dielectric layer. The substrate 110 may include a region NT where n-type devices (e.g., NMOSFET) are to be formed and a region PT where p-type devices (e.g., PMOSFET) are to be formed. The region NT may be doped with p-type dopants (e.g., boron), to form a p-type well PW therein. The region PR may be doped with n-type dopants (e.g., phosphorus or arsenic), to form a n-type well NW wherein.

An epitaxial stack 120 is formed over the substrate 110. The epitaxial stack 120 includes epitaxial layers 122 of a first composition interposed by epitaxial layers 124 of a second composition. The first and second compositions can be different. In some embodiments, the epitaxial layers 122 are SiGe and the epitaxial layers 124 are silicon (Si). However, other embodiments are possible including those that provide for a first composition and a second composition having different oxidation rates and/or etch selectivity. In some embodiments, the epitaxial layers 122 include SiGe and where the epitaxial layers 124 include Si, the Si oxidation rate of the epitaxial layers 124 is less than the SiGe oxidation rate of the epitaxial layers 122.

The epitaxial layers 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The use of the epitaxial layers 124 to define a channel or channels of a device is further discussed below. It is noted that two layers of the epitaxial layers 122 and two layers of the epitaxial layers 124 are alternately arranged as illustrated in FIG. 1. It can be appreciated that any number of epitaxial layers can be formed in the epitaxial stack 120; the number of layers depending on the desired number of channels regions for the transistor. In some embodiments, the number of epitaxial layers 124 is between 2 and 10, such as 2, 3, or 4.

In some embodiments of the present disclosure, the bottommost epitaxial layer 122m is formed with a thickness 122T1 greater than the thickness 122T2 of the epitaxial layers 122 above the bottommost epitaxial layer 122m. For example, a ratio of the thickness 122T1 and the thickness 122T2 is in a range from about 1.05 to about 2. If the ratio of the thickness 122T1 and the thickness 122T2 is less than about 1.05, the device performance may not be improved. If the ratio of the thickness 122T1 and the thickness 122T2 is greater than about 2, the device size may be enlarged unnecessarily, or the vertical distance between the channel layers may be too small to receive metal gate.

In some embodiments, the thickness 122T2 of the epitaxial layers 122 above the bottommost epitaxial layer 122m may be uniform, and the epitaxial layers 124 of the stack 120 are formed with a uniform thickness less than thickness 122T1 and thickness 122T2. The epitaxial layers 124 may serve as channel region(s) for a subsequently-formed multi-gate device and the thickness is chosen based on device performance considerations. The epitaxial layers 122 in channel regions(s) may eventually be removed and serve to define a vertical distance between adjacent channel region(s) for a subsequently-formed multi-gate device and the thickness is chosen based on device performance considerations. Accordingly, the epitaxial layers 122 may also be referred to as sacrificial layers, and epitaxial layers 124 may also be referred to as channel layers.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124 include the same material as the substrate 110. In some embodiments, the epitaxially grown layers 122 and 124 include a different material than the substrate 110. As stated above, in at least some examples, the epitaxial layers 122 include an epitaxially grown silicon germanium (SiGe) layer and the epitaxial layers 124 include an epitaxially grown silicon (Si) layer. Alternatively, in some embodiments, either of the epitaxial layers 122 and 124 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 122 and 124 may be chosen based on providing differing oxidation and/or etching selectivity properties. In some embodiments, the epitaxial layers 122 and 124 are substantially dopant-free (i.e., having an extrinsic dopant concentration from about 0 cm⁻³ to about 1×10¹⁸ cm⁻³), where for example, no intentional doping is performed during the epitaxial growth process.

Reference is made to FIGS. 2A and 2B. The epitaxial stack 120 and the substrate 110 are patterned, thereby forming plural fins FS. The fins FS may extend along direction X. The patterning may include suitable lithography process and etching processes. The lithography process (e.g., photolithography or e-beam lithography) may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., reactive ion etching), wet etching, and/or other etching methods. In some embodiments, masks are formed over the epitaxial stack 120 by the photolithography process. The masks are used to protect regions of the substrate 110 and the epitaxial stack 120, while etching processes form trenches T1 in unprotected regions through the epitaxial stack 120 and into the substrate 110, thereby leaving the plurality of extending fins FS.

In some alternative embodiments, the fins FS may be fabricated using suitable processes including double-patterning or multi-patterning processes. The double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120. The etching process can include dry etching, wet etching, reactive ion etching (RIE), and/or other suitable processes.

Numerous other embodiments of methods to form the fins on the substrate may also be used including, for example, defining the fin region (e.g., by mask or isolation regions) and epitaxially growing the epitaxial stack 120 in the form of the fins FS. In various embodiments, each of the fins FS includes a base portion 112 patterned from the semiconductor substrate 110 and portions of each of the epitaxial layers 122 and 124 of the epitaxial stack 120.

Isolation structures 130 are formed in the trenches T1 between the fins FS. The isolation structures 130 may be referred to as shallow trench isolation (STI) structures. By way of example and not limitation, a dielectric layer is first deposited over the substrate 110, filling the trenches T1 with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a sub-atmospheric CVD (SACVD) process, a flowable CVD process, an ALD process, a physical vapor deposition (PVD) process, and/or other suitable processes. In some embodiments, the dielectric layer may include a multi-layer structure, for example, having one or more liner layers. In some embodiments, after deposition of the dielectric layer, the deposited dielectric material is thinned and planarized, for example by a chemical mechanical polishing (CMP) process.

In the layouts, regions between the isolation structures 130 are indicated as oxide-defined (OD) regions, which correspond to the fins FS. The isolation (or STI) structures 130 are recessed in an etch back process, such that the OD regions (e.g., fins FS) has exposed sidewall extending above the isolation structure 130. In some embodiments, the recessing process may include a dry etching process, a wet etching process, and/or a combination thereof. In some embodiments, a recessing depth is controlled (e.g., by controlling an etching time) so as to result in a target height of the exposed upper portion of the fins FS. In some embodiments, the target height for STI recessing is in a range from about 30 nanometers to about 80 nanometers. The target height may expose sidewalls of the OD regions (e.g., fins FS). In the illustrated embodiments, the target height exposes each of the epitaxial layers 122 and 124 of the epitaxial stack 120 in the fins FS.

Reference is made to FIGS. 3A-3C. A dummy gate dielectric layer 142 is then conformally deposited in the trenches T1 and over the isolation structures 130. In some embodiments, the dummy gate dielectric layer 142 may include SiO₂, silicon nitride, a high-k dielectric material and/or other suitable material. In various examples, the dummy gate dielectric layer 142 may be deposited by a CVD process, a subatmospheric CVD (SACVD) process, a flowable CVD process, an ALD process, a PVD process, or other suitable process. By way of example, the dummy gate dielectric layer 142 may be used to prevent damages to the fins FS by subsequent processes (e.g., subsequent formation of the dummy gate structures).

Dummy gate structures 140 are formed in accordance with some embodiments of the present disclosure. The dummy gate structures 140 may extend along the direction Y intersecting the direction X that the fins FS extend along. For example, the direction Y is orthogonal to the direction X. In some embodiments, the dummy gate structures 140 each include the dummy gate dielectric layer 142, a dummy gate electrode layer 144 and a hard mask 146. In some embodiments, the dummy gate structures 140 are formed by various process steps such as layer deposition, patterning, etching, as well as other suitable processing steps. Exemplary layer deposition processes include CVD (including both low-pressure CVD and plasma-enhanced CVD), PVD, ALD, thermal oxidation, e-beam evaporation, or other suitable deposition techniques, or combinations thereof. In forming the gate structures for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods.

In some embodiments, the dummy gate electrode layer 144 may include polycrystalline silicon (polysilicon). In some embodiments, the hard mask 146 includes an oxide layer such as a pad oxide layer that may include SiO₂, and a nitride layer such as a pad nitride layer that may include Si₃N₄ and/or silicon oxynitride. In some embodiments, after patterning the dummy gate electrode layer 144, exposed portions of the dummy gate dielectric layer 142 not covered under the patterned dummy gate electrode layer 144 are removed from source/drain regions of the fins FS. The etch process may include a wet etch, a dry etch, and/or a combination thereof. The etch process is chosen to selectively etch the dummy gate dielectric layer 142 without substantially etching the fins FS, the dummy gate electrode layer 144 and the hard mask 146.

In some embodiments, gate spacers 150 are formed on sidewalls of the dummy gate structures 140. The gate spacers 150 may include a dielectric material such as SiO₂, Si₃N₄, carbon doped oxide, nitrogen doped oxide, porous oxide, or the combination thereof. The gate spacers 150 may include multiple dielectric materials. In some embodiments, the gate spacers 150 may further include air gaps. In some embodiments of formation of the gate spacers 150, a spacer material layer is first deposited over the substrate 110. The spacer material layer may be a conformal layer that is subsequently etched to form gate sidewall spacers on sidewalls of the dummy gate structures 140. In the illustrated embodiments, a spacer material layer is disposed conformally on top and sidewalls of the dummy gate structures 140. By way of example, the spacer material layer may be formed by depositing a dielectric material over the gate structures 140 using processes such as, CVD process, a subatmospheric CVD (SACVD) process, a flowable CVD process, an ALD process, a PVD process, or other suitable process. An anisotropic etching process is then performed on the deposited spacer material layer to expose portions of the fins FS not covered by the dummy gate structures 140 (e.g., in source/drain regions of the fins FS denoted as “S” and “D”). Portions of the spacer material layer directly above the dummy gate structures 140 may be completely removed by this anisotropic etching process. Portions of the spacer material layer on sidewalls of the dummy gate structures 140 may remain, forming gate sidewall spacers, which are denoted as the gate spacers 150, for the sake of simplicity. In some embodiments, the gate spacers 150 may have a thickness 150T in a range from about 3 nanometers to about 15 nanometers. If the thickness 150T of the gate spacers 150 is out of the range, device performance may degrade. The gate spacers 150 serve to isolate metal gates from source/drain contacts formed in subsequent processing.

Reference is made to FIG. 4. Exposed portions of the semiconductor fins FS that extend laterally beyond the gate spacers 150 (e.g., in source/drain regions of the fins FS) are etched by using, for example, an anisotropic etching process that uses the dummy gate structures 140 and the gate spacers 150 as an etch mask, resulting in recesses R1 into the semiconductor fins FS and between corresponding dummy gate structures 140. In some embodiments, the recesses R1 extends through the stack 120 to the substrate 110 for exposing the sacrificial layers 122 and channel layers 124. After the anisotropic etching, end surfaces of the sacrificial layers 122 and channel layers 124 are substantially aligned with respective outermost sidewalls of the gate spacers 150, due to the anisotropic etching.

The sacrificial layers 122 may be laterally or horizontally recessed by using suitable etch techniques, resulting in lateral recesses R2 each vertically between corresponding channel layers 124. This step may be performed by using a selective etching process. By way of example and not limitation, the sacrificial layers 122 are SiGe and the channel layers 124 are silicon allowing for the selective etching of the sacrificial layers 122. In some embodiments, the selective wet etching includes an APM etch (e.g., ammonia hydroxide-hydrogen peroxide-water mixture) that etches SiGe at a faster etch rate than it etches Si. In some embodiments, the selective etching includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower than oxidation rate of SiGe, the channel layers 124 remain substantially intact during laterally recessing the sacrificial layers 122. As a result, the channel layers 124 laterally extend past opposite end surfaces of the sacrificial layers 122.

After the sacrificial layers 122 have been laterally recessed, inner spacers 160 are formed in the recesses R2 left by the lateral etching of the sacrificial layers 122. The inner spacers 160 may be made of a different dielectric material than that of the gate spacers 150. In some embodiments, the inner spacers 160 have a higher k value (or dielectric constant) different from that of the gate spacers 150. Thus, when the inner spacers 160 are thinner than the gate spacers 150, the inner spacers 160 can still well protect source/drain regions from etchants in channel release process in subsequent process. In some alternative embodiments, the inner spacers may have a lower k value (or dielectric constant) than that of the gate spacers 150. For example, the inner spacers 160 includes a suitable dielectric material, such as SiO₂, Si₃N₄, SiON, SiOC, SiOCN, the like, or the combination thereof. In some embodiments, the inner spacers 160 may further include air gaps. Formation of the inner spacers 160 may include depositing an inner spacer material layer is formed to fill the recesses R2. The inner spacer material layer may be deposited by a suitable deposition method, such as ALD. After the deposition of the inner spacer material layer, an anisotropic etching process may be performed to trim the deposited inner spacer material, such that only portions of the deposited inner spacer material that fill the recesses left by the lateral etching of the sacrificial layers 122 are left. After the trimming process, the remaining portions of the deposited inner spacer material are denoted as inner spacers 160. In some embodiments, a thickness of the inner spacers 160 may be in a range from about 2 nanometers to about 12 nanometers. If the thickness 160T of the inner spacers 160 is out of the range, device performance may degrade. The inner spacers 160 serve to isolate metal gates from source/drain epitaxial structures formed in subsequent processing.

In some embodiments of the present embodiments, the etching time/duration of the lateral etching of the sacrificial layers 122 is controlled such that the lateral depth of the lateral recesses R2 is less than the thickness 150T of the gate spacers 150, which in turn result in that the inner spacers 160 are formed with a thickness 160T less than the thickness 150T of the gate spacers 150, and the gate structure 140 have a width less than the width of the sacrificial layers 122. Through the configuration, while maintaining gate length for gate control, capacitance between contact and gate can be reduced. For example, a difference between the thickness 160T of the inner spacers 160 and the thickness 150T of the gate spacers 150 may be in a range from about 0.5 nanometer to about 5 nanometers. For example, a ratio of the thickness 160T of the inner spacers 160 and the thickness 150T of the gate spacers 150 may be in a range from about 1.1 to about 1.5. If the difference between the thickness 160T and the thickness 150T is less than about 0.5 nanometer, or the ratio of the thickness 160T and the thickness 150T is less than about 1.1, the capacitance between contact and gate may not be reduced effectively. If the difference between the thickness 160T and the thickness 150T is greater than about 5 nanometers, or the ratio of the thickness 160T and the thickness 150T is greater than about 1.5, the space between the gate spacers 150 may be too narrow to receive metals in subsequent gate replacement process.

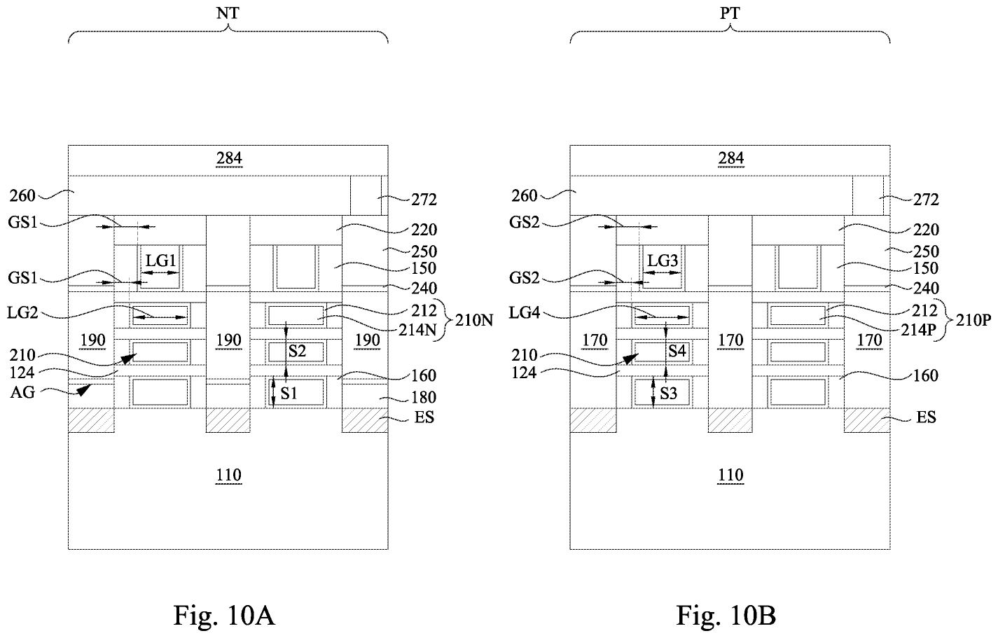

In present some embodiments, intrinsic epitaxial features ES may be formed in the recesses R1. In some embodiments, an epitaxial growth process is performed to grow an epitaxial material in the recesses R1 and R2. The epitaxial material may have a composition similar to the substrate 110. For example, the substrate 110 and the intrinsic epitaxial features ES are Si. In some alternative embodiments, the intrinsic epitaxial features ES may have a composition different from that of the substrate 110. For example, the substrate 110 includes Si, and the intrinsic epitaxial features ES may include SiGe. The intrinsic epitaxial features ES may have a non-observable interface with the substrate 110, and thus serve as a portion of the substrate 110. In some other embodiments, the intrinsic epitaxial features ES may have a observable interface with the substrate 110 as illustrated later in FIGS. 10A and 10B.

In some embodiments, the intrinsic epitaxial features ES are not intentionally doped, for example, not having intentionally placed dopants, but rather having a doping resulting from process contaminants. For example, the intrinsic epitaxial features ES are not intentional doped (NID) semiconductor layers and thus free from p-type dopants (e.g., boron) and n-type dopants (e.g., phosphorous) in subsequent doped source/drain epitaxial features. Alternatively, the intrinsic epitaxial features ES may be doped with p-type dopants (e.g., boron) or n-type dopants (e.g., phosphorous), and with a doping concentration lower than that of the doped source/drain epitaxial features. For example, the intrinsic epitaxial features ES have dopant concentration lower than about 10¹³/cm³.

In some embodiments, in order to prevent the epitaxial material of the intrinsic epitaxial features ES from being inadvertently formed on end surfaces of the channel layers 124, the intrinsic epitaxial features ES can be grown in a bottom-up manner, in accordance with some embodiments of the present disclosure. By way of example and not limitation, the intrinsic epitaxial features ES can be grown by an epitaxial deposition/partial etch process, which repeats the epitaxial deposition/partial etch process at least once. Such repeated deposition/partial etch process is also called a cyclic deposition-etch (CDE) process. In some embodiments, these intrinsic epitaxial features ES are grown by selective epitaxial growth (SEG), where an etching gas is added to promote the selective growth of the epitaxial material from the bottom surface of the recesses R1 that has a first crystal plane, but not from the vertical end surfaces of the channel layers 124 that have a second crystal plane different from the first crystal plane.

Reference is made to FIGS. 5A and 5B. Source/drain epitaxial structures 170 and 190 are formed in the recesses R1 in the fins FS. The source/drain epitaxial structures 170 and 190 may be formed by performing an epitaxial growth process that provides an epitaxial material on the fins FS. Suitable epitaxial processes include CVD deposition techniques (e.g., vapor-phase epitaxy (VPE) and/or ultra-high vacuum CVD (UHV-CVD)), molecular beam epitaxy, and/or other suitable processes.

The source/drain epitaxial structures 170 and 190 may be in-situ doped during the epitaxial process by introducing doping species including: p-type dopants, such as boron; n-type dopants, such as phosphorus or arsenic; and/or other suitable dopants including combinations thereof. If the source/drain epitaxial structures 170 and 190 are not in-situ doped, an implantation process (i.e., a junction implant process) is performed to dope the source/drain epitaxial structures 170 and 190. In some exemplary embodiments, the source/drain epitaxial structures 170 in a PFET device include SiGe doped with boron, or SiGeC doped with boron, Ge doped with boron, Si doped with boron, or combination. The p-type doping concentration of the source/drain epitaxial structures 170 (e.g., boron) in the PFET device may be in a range from about 1E19/cm³ to about 6E20/cm³. In some exemplary embodiments, the source/drain epitaxial structures 190 in an NFET device include SiP. SiC, SiPC, SiAs, Si, or combination thereof. The n-type doping concentration of the source/drain epitaxial structures 190 (e.g., phosphorus, arsenic, or both) in the NFET device may be in a range from about 2E19/cm³ to about 3E21/cm³.

In some embodiments, a first mask is formed to cover the region NT and expose the region PT, and the source/drain epitaxial structures 170 are epitaxially grown over the region PT. With the coverage of the first mask, the epitaxial growth process may use gaseous and/or liquid precursors, which interact with the composition of semiconductor materials of the substrate 110 and the channel layers 124 in the region PT, thereby forming the source/drain epitaxial structures 170, while the substrate 110 and the channel layers 124 in the region NT is free from the interaction with the gaseous and/or liquid precursors. The first mask is removed by suitable etching/removal process after the formation of the source/drain epitaxial structures 170. A second mask may then be formed to cover the region PT and expose the region NT, and the source/drain epitaxial structures 190 are then epitaxially grown over the region NT. In some embodiments, an isolation layer 180 is formed to cover the substrate 110 in the region NT. With the coverage of the second mask and the isolation layer 180, the epitaxial growth process may use gaseous and/or liquid precursors, which interact with the composition of semiconductor materials of the channel layers 124 in the region NT, thereby forming the source/drain epitaxial structures 190, while the substrate 110 and the channel layers 124 in the region PT is free from the interaction with the gaseous and/or liquid precursors. The second mask is removed by suitable etching/removal process after the formation of the source/drain epitaxial structures 190.

In some embodiments of the present disclosure, the epitaxial growth of the source/drain epitaxial structures 190 is performed after the epitaxial growth of the source/drain epitaxial structures 170. In some other embodiments, the epitaxial growth of the source/drain epitaxial structures 170 is performed after the epitaxial growth of the source/drain epitaxial structures 190.

The isolation layer 180 may be formed over the region NT and not formed over the region PT, for example, prior to the formation of the source/drain epitaxial structures 190 and after the formation of the source/drain epitaxial structures 170. In some embodiments, with the second mask covering the region PT, the isolation layer 180 is deposited in the region NT by a deposition/partial etch process, and thus the isolation layer 180 may be located at the bottom of the recess R1, leaving the channel layers 124 exposed. The configuration of the isolation layer 180 can reduce the capacitances between gate and source/drain regions, leakage from source/drain regions to the well region (both source cutoff current (Is_{off}), and junction capacitance between the source/drain regions and the well region. The dielectric material may include silicon oxide, silicon nitride, silicon oxynitride, the like, or the combination thereof. The isolation layer 180 can be a single dielectric layer, or multiple dielectric layers. In some embodiments, for allowing growth of the source/drain epitaxial structures 190 from the bottommost channel layer 124, a top surface of the isolation layer 180 is higher than a top surface of the semiconductor substrate 110 and lower than a bottom surface of the bottommost channel layer 124. In some embodiments, a vertical distance between the top surface of the isolation layer 180 and the bottom surface of the bottommost channel layer 124 is less than the thickness 122T2 of the sacrificial layer 122 (or the vertical spacing S2/S4 between the channel layers 124 illustrated later).

A thickness of the isolation layer 180 may be in a range from about 1 nanometer to about 30 nanometers. If the thickness of the isolation layer 180 is less than about 1 nanometer, the isolation layer 180 may not lower capacitance between the source/drain epitaxial structures 190 and the gate by reducing the effective area of the plate therebetween. If the thickness of the isolation layer 180 is greater than about 30 nanometers, the isolation layer 180 may be in contact with the bottommost channel layer 124, and therefore isolating the bottommost channel layer 124 from the source/drain epitaxial structures 190. In some embodiments, the thickness of the isolation layer 180 may be less than the thickness 122T1 of the bottommost sacrificial layer 122 (or the vertical spacing S1/S3 between the channel layer 124 and the substrate 110 illustrated later). The source/drain epitaxial structures 190 grown from the channel layers 124 may have a bottom surface in contact with the isolation layer 180 in the present embodiments. In some other embodiments, the bottom surface of the source/drain epitaxial structures 190 may not be in contact with the isolation layer 180.

After the epitaxial growth of the source/drain epitaxial structures 170 and 190, a dielectric material 200 is formed over the substrate 110 and filling the space between the dummy gate structures 140. In some embodiments, the dielectric material 200 includes a contact etch stop layer (CESL) and an interlayer dielectric (ILD) layer formed in sequence. In some examples, the CESL includes a silicon nitride layer, silicon oxide layer, a silicon oxynitride layer, and/or other suitable materials having a different etch selectivity than the ILD layer. The CESL may be formed by plasma-enhanced chemical vapor deposition (PECVD) process and/or other suitable deposition or oxidation processes. The ILD layer is then deposited over the CESL. In some embodiments, the ILD layer includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL. The ILD layer may be deposited by a PECVD process or other suitable deposition technique.

After depositing the dielectric material 200, a planarization process may be performed to remove excessive materials of the dielectric material 200. For example, a planarization process includes a chemical mechanical planarization (CMP) process which removes portions of the dielectric material 200 overlying the dummy gate structures 200 and planarizes a top surface of the integrated circuit structure. In some embodiments, the CMP process also removes the hard mask layer 146 in the dummy gate structures 140 (as shown in FIG. 4) and exposes the dummy gate electrode layer 144.

Reference is made to FIGS. 6A-6D. The dummy gate structures 140 (referring to FIGS. 5A and 5B) are replaced with high-k/metal gate structures 210. The high-k/metal gate replacement process may include removing the dummy gate structures 140 (referring to FIGS. 5A and 5B), and removing the sacrificial layers 122 (referring to FIGS. 5A and 5B) therebelow. The removals form gate trenches GT between the gate spacers 150, openings/spaces O1 between the bottommost channel layer 124 and the substrate 110, and openings/spaces O2 between neighboring channel layers 124. Replacement gate structures 210 are respectively formed in the gate trenches GT and openings/spaces O1 and O2 to surround each of the channel layers 124 suspended in the gate trenches GT.

In the illustrated embodiments, the dummy gate structures 140 (referring to FIGS. 5A are 5B) are removed by using a selective etching process (e.g., selective dry etching, selective wet etching, or a combination thereof) that etches the materials in dummy gate structures 140 (referring to FIGS. 5A are 5B) at a faster etch rate than it etches other materials (e.g., gate spacers 150 and the dielectric material 200), thus resulting in gate trenches GT between corresponding gate spacers 150, with the top surface and sidewalls of the fins FS exposed in the gate trenches GT. Subsequently, the sacrificial layers 122 (referring to FIGS. 5A are 5B) in the gate trenches GT are etched by using another selective etching process that etches the sacrificial layers 122 at a faster etch rate than it etches the channel layers 124, thus forming openings/spaces O1 between the bottommost channel layer 124 and the substrate 110 and openings/spaces O2 between neighboring channel layers 124. In this way, the channel layers 124 become nanosheets suspended over the substrate 110 and between the source/drain epitaxial structures 170/190. This step is also called a channel release process. In some embodiments, the nanosheets 124 can be interchangeably referred to as nanostructures, nanowires, nanoslabs and nanorings, depending on their geometry. For example, in some other embodiments the channel layers 124 may be trimmed to have a substantial rounded shape (i.e., cylindrical) due to the selective etching process for completely removing the sacrificial layers 122 (referring to FIGS. 5A are 5B). In that case, the resultant channel layers 124 can be called nanowires.

Following the profile of the sacrificial layers 122 (referring to FIGS. 5A are 5B), a vertical spacing S1/S3 between the bottommost channel layer 124 and the substrate 110 is greater than a vertical spacing S2/S4 between two adjacent the channel layers 124. The narrower sheet-to-sheet distance (i.e., the vertical spacing S2/S4) is advantageous for source/drain depth reduction, thereby lowering capacitance between gate and source/drain regions as well as lowering resistance for source/drain regions. The wider sheet-to-bottom Si distance (i.e., the vertical spacing S1/S3) is advantageous for manufacturing margin for forming the isolation layers 180 and the source/drain sidewall inner spacers 160. For example, a thickness of the epitaxial layers 124 may be in a range from about 4 nanometers to about 8 nanometers, the vertical spacing S2/S4 may be in a range from about 6 nanometers to about 16 nanometers, and a combination of the thickness of the epitaxial layers 124 and the vertical spacing S2/S4 may be in a range from about 12 nanometers to about 24 nanometers. And, the vertical spacing S1/S3 may be in a range from about 7 nanometers to about 30 nanometers. If the spacings, and the thickness of the epitaxial layers 124 are out of the range, the device performance may degrade. In some embodiments, a ratio of the vertical spacing S1/S3 and the vertical spacing S2/S4 is in a range from about 1.05 to about 2. If the ratio of the vertical spacing S1/S3 and the vertical spacing S2/S4 is less than about 1.05, the device performance may not be improved. If the ratio of the vertical spacing S1/S3 and the vertical spacing S2/S4 is greater than about 2, the device size may be enlarged unnecessarily, or the vertical spacing S1/S3 between the channel layers 124 may be too small to receive metal gate.

In some embodiments, the sacrificial layers 122 are removed by using a selective wet etching process. In some embodiments, the sacrificial layers 122 are SiGe and the channel layers 124 are silicon allowing for the selective removal of the sacrificial layers 122. In some embodiments, the selective wet etching includes an APM etch (e.g., ammonia hydroxide-hydrogen peroxide-water mixture). In some embodiments, the selective removal includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower (sometimes 30 times lower) than oxidation rate of SiGe, the channel layers 124 may remain substantially intact during the channel release process. In some embodiments, both the channel release step and the previous step of laterally recessing sacrificial layers use a selective etching process that etches SiGe at a faster etch rate than etching Si, and therefore these two steps may use the same etchant chemistry in some embodiments. In this case, the etching time/duration of channel release step is longer than the etching time/duration of the previous step of laterally recessing sacrificial layers, so as to completely remove the sacrificial SiGe layers.

The gate structures 210 may be final gates of GAA FETs. The final gate structure may be a high-k/metal gate stack, however other compositions are possible. In some embodiments, each of the gate structures 210 forms the gate associated with the multi-channels provided by the plurality of nanosheets 124. For example, high-k/metal gate structures 210 are formed within the openings O1 and O2 provided by the release of nanosheets 124. In various embodiments, the high-k/metal gate structure 210 includes a gate dielectric layer 212 around the nanosheets 124 and a gate metal layer 214 formed around the gate dielectric layer 212 and filling a remainder of gate trenches GT1. Formation of the high-k/metal gate structures 210 may include one or more deposition processes to form various gate materials, followed by a CMP processes to remove excessive gate materials. In some embodiments, the vertical spacing S1/S3 may also be referred to as a height of the gate structures 210 below the bottommost channel layer 124, and the vertical spacing S2/S4 may also be referred to as a height of the gate structures 210 between the channel layers 124.

In some embodiments, the gate dielectric layer 212 includes an interfacial layer formed around the nanosheets 124 and a high-k gate dielectric layer formed around the interfacial layer. The interfacial layer may be silicon oxide formed on exposed surfaces of semiconductor materials in the gate trenches GT by using, for example, thermal oxidation, chemical oxidation, wet oxidation or the like. As a result, surface portions of the nanosheets 124 and the substrate 110 exposed in the gate trenches GT1 are oxidized into silicon oxide to form interfacial layer. The interfacial layer may be doped with nitrogen. The k value of the high-k gate dielectric layer may be greater than about 9, or even greater than about 13. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), other metal-containing dielectrics, the like, or combinations thereof.

In some embodiments, the gate metal layer 214 includes one or more metal layers. For example, the gate metal layer 214 may include one or more work function metal layers stacked one over another. The one or more work function metal layers in the gate metal layer 214 provide a suitable work function for the high-k/metal gate structures 210. The work function metal layers may include TIN, TaN, TiAl, TiAlN, TaAl, TaAlN, TaAlC, TaCN, WNC, Co, Ni, Pt, W, or combination thereof. NMOSFET and PMOSFET may include the same work function material, or different work function materials. For example, n-type work function metals in the region NT for NMOSFET may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. P-type work function metal in the region PT for PMOSFET may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. One for more lithography and patterning processes may be performed for forming the work-function metals for NMOSFET and forming the work-function metals for PMOSFET. In some embodiments, the gate metal layer 214 may include a fill metal filling up a remainder of gate trenches GT1. The fill metal in the gate metal layer 214 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. The gate structures 210 may be denoted as gate structures 210N and 210P for NMOSFET and PMOSFET, respectively, and the gate metal layer 214 may be denoted as gate metal layer 214N and 214P for NMOSFET and PMOSFET, respectively. The gate metal layer 214N and 214P may include different metal materials, and thus have an interface therebetween.

Referring to FIG. 6C and 6D, as the gate structure 140 and the sacrificial layers 122 (referring to FIGS. 5A and 5B) have different thicknesses, the gate metal layer 214N/214P may have a width LG1/LG3 between the gate spacers 150 and a width LG2/LG4 between the inner spacer 160, in which the width LG1/LG3 is less than the width LG2/LG4. For example, a ratio of the width LG2/LG4 and the width LG1/LG3 is in a range from about 1.05 to about 2. If the ratio of the width LG2/LG4 and the width LG1/LG3 is less than about 1.05, the device performance may not be improved. If the ratio of the width LG2/LG4 and the width LG1/LG3 is greater than about 2, the filling of materials of the gate metal layer 214N/214P in the space between the gate spacers 150 may become difficult.

After the formation of the high-k/metal gate structure 210, top surfaces of the high-k/metal gate structure 210 and the gate spacers 150 may be recessed by suitable etching process. The dielectric material 200 may have a higher etch resistance to the etching process than that of the high-k/metal gate structure 210 and the gate spacers 150. Hard masks 220 may be formed over the recessed top surfaces of the metal gate structures 210 and the gate spacers 150. Formation of the hard masks 220 may include depositing suitable dielectric materials over the recessed top surfaces of the high-k/metal gate structure 210 and the gate spacers 150, followed by a CMP process. The dielectric material of the hard masks 220 may include SiOC, SiON, SiOCN, nitride base dielectric, metal oxide dielectric, HfO₂, Ta₂O₅, TiO₂, ZrO₂, Al₂O₃, Y₂O₃, the like, or the combination thereof. The hard masks 220 may have a thickness in a range from about 2 nanometers to about 60 nanometers. Through the configurations, the high-k/metal gate structure 210 and the gate spacers 150 are capped and protected by the hard masks 220.

Gate end dielectrics 230 may either be disposed between gate structures 210 or at an end of a gate structure 210 after a gate cut process. In some embodiments, the gate end dielectric 230 may be referred to as dielectric plugs. The gate end dielectric layer 230 may include suitable dielectric materials, such as oxide, Si₃N₄, other nitride-base dielectric, carbon-base dielectric, high k material (e.g., having a k value equal to or greater than 9), or other suitable dielectric material. Formation of the gate end dielectric 230 may include etching away portions of the metal gate structures 210 and the hard masks 220 to expose underlying dielectric materials (e.g., the isolation structures 130), and depositing the suitable gate end dielectric materials over the underlying dielectric materials (e.g., the isolation structures 130). A CMP process may be performed to remove excess portions of the gate end dielectric materials, leaving the remaining portions forming the gate end dielectric 230.

Reference is made to FIGS. 7A-7E. Source/drain contacts 250 are formed over the source/drain epitaxial structures 170 and 190. In some embodiments, the formation of the source/drain contacts 250 includes etching source/drain contact openings through the dielectric material 200 to expose top surfaces of the source/drain epitaxial structures 170 and 19, and depositing one or more metal materials into the source/drain contact openings. The metal materials may include W, Ru, Co, Cu, Ti, TiN, Ta, TaN, Mo, Ni, Pt, Ir, Rh, the like or combinations thereof. The metal materials are deposited to fill the source/drain contact openings by using suitable deposition techniques (e.g., CVD, PVD, ALD, the like or combinations thereof). Subsequently, a CMP process can be performed to remove excess metal materials outside the source/drain contact openings, while leaving metal materials in the source/drain contact openings to serve as the source/drain contacts 250. The source/drain contacts 250 may include a single metal material or multiple metal material layers.

In some embodiments, prior to depositing the metal materials of the source/drain contacts 250, metal silicide regions 240 may be formed on exposed top surfaces of the source/drain epitaxial structures 170 and 190 by using a silicidation process. Silicidation may be formed by blanket depositing a metal layer over the exposed source/drain epitaxial structures 170 and 190, annealing the metal layer such that the metal layer reacts with silicon (and germanium if present) in the source/drain epitaxial structures 170 and 190 to form the metal silicide regions 240, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. Thus, metal silicide regions 240 may be between the source/drain contacts 250 and the source/drain epitaxial structures 170 and 190.

In the present embodiments, the source/drain contacts 250 are self-aligned structures and have a top surface substantially level with the hard masks 220. In such embodiments, the source/drain contacts 250 may be in contact with the gate spacers 150. In some alternative embodiments, the source/drain contacts 250 are not self-aligned structures and have a top surface higher with the hard masks 220. In such embodiments, the source/drain contacts 250 may be spaced apart from the gate spacers 150 by the dielectric material 200.

Referring to FIGS. 7B and 7C, as the gate spacers 150 and the inner spacers 160 have different thicknesses, the source/drain contacts 250 may be isolated from the gate structure 210 by a distance GS1 greater than a distance GS2 between the source/drain epitaxial structure 170/190 and the gate structure 210. For example, a difference between the distance GS1 and the distance GS2 may be in a range from about 0.5 nanometer to about 5 nanometers. If the difference between the distance GS1 and the distance GS2 is less than about 0.5 nanometer, the capacitance between source/drain contact and gate may not be reduced effectively. If the difference between the distance GS1 and the distance GS2 is greater than about 5 nanometers, the space between the gate spacers 150 may be too narrow to receive metals.

FIGS. 8A-8F illustrate formation of metal vias 272, 274 and a front-side multilayer interconnection (MLI) structure FMI over the substrate 110. Formation of the metal vias 272 and 274 may include depositing an ILD layer 260 over the structure of FIGS. 7A-7E, etching openings in the ILD layer 260 and the hard masks 220, and filling the openings with one or more suitable conductive materials. In some embodiments, the ILD layer 260 may include low-k dielectric materials having k values, for example, lower than about 4.0 or even 2.0 disposed between such conductive features. In some embodiments, the ILD layer 260 may be made of, for example, PSG, BPSG, FSG, SiOₓC_{y}, Spin-On-Glass, Spin-On-Polymers, silicon oxide, silicon oxynitride, combinations thereof, or the like, formed by any suitable method, such as spin-on coating, CVD, PECVD, or the like. The conductive materials may comprise metal materials such as W, Ru, Co, Cu, Ti, TiN, Ta, TaN, Mo, Ni, combinations thereof, or the like. Remaining portions of the conductive materials in the openings may form the metal vias 272, 274. respectively. The metal via 272 may be in contact with the source/drain contact 250. The metal via 274 may extends through the hard mask 220 and be in contact with the gate metal layer 214N/214P. The metal via 272 may be denoted as V_SD in the layout in FIG. 8A, and the metal via 274 may be denoted as VD in the layout in FIG. 8A.

The front-side MLI structure 280 is formed over the metal vias 272 and 274. The front-side MLI structure 280 may include at least one metallization layers. The number of metallization layers may vary according to design specifications of the integrated circuit structure. Only one metallization layer 280 is illustrated in FIGS. 8A-8F for the sake of simplicity. The metallization layer 280 is the metallization layer closest to the transistors. The metallization layer 280 may be denoted as M1 in the layout in FIG. 8A. The metallization layer 280 may also be referred to as the lowest metallization layer of the front-side MLI structure FMI. The metallization layers each comprise one or more inter-metal dielectric (IMD) layers, one or more horizontal interconnects respectively extending horizontally in the IMD layers. For example, the metallization layer 280 comprises IMD layers 282 and horizontal interconnects (e.g., metal lines 284). Some of the metallization layers above the lowest metallization layer 280 may include one or more vertical interconnects respectively extending vertically in the IMD layers. The metal lines 284 of the lowest metallization layer 280 of the front-side MLI structure FMI may include a high power rail Vdd and a lower power rail Vss. The metal lines 284 of the lowest metallization layer 280 of the front-side MLI structure FMI may be in contact with the metal vias 272, 274, respectively, thereby establishing power electrical connection from the metal lines 284 (e.g., the high power rail Vdd and/or the lower power rail Vss) to the source epitaxial structure 170/190 and electrical connection from the metal lines 284 to the gate metal layer 214N/214P.

The metallization layer 280 can be formed using, for example, a single damascene process, a dual damascene process, the like, or combinations thereof. In some embodiments, the IMD layers 282 may include low-k dielectric materials having k values, for example, lower than about 4.0 or even 2.0 disposed between such conductive features. In some embodiments, the IMD layers 282 may be made of, for example, PSG, BPSG, FSG, SiOₓC_{y}, Spin-On-Glass, Spin-On-Polymers, silicon oxide, silicon oxynitride, combinations thereof, or the like, formed by any suitable method, such as spin-on coating, CVD, PECVD, or the like. The metal lines 284 may comprise metal materials such as W, Ru, Co, Cu, Ti, TiN, Ta, TaN, Mo, Ni, combinations thereof, or the like. In some embodiments, the metal lines 284 may further comprise one or more barrier/adhesion layers (not shown) to protect the respective IMD layers 282 from metal diffusion (e.g., copper diffusion) and metallic poisoning. The one or more barrier/adhesion layers may comprise titanium, titanium nitride, tantalum, tantalum nitride, or the like, and may be formed using PVD. CVD, ALD, or the like.

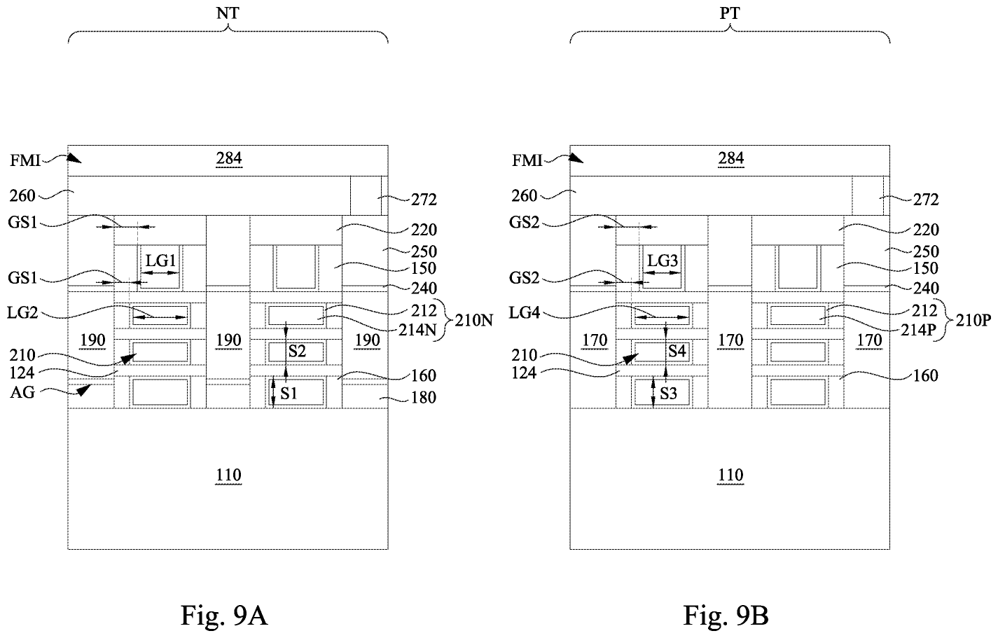

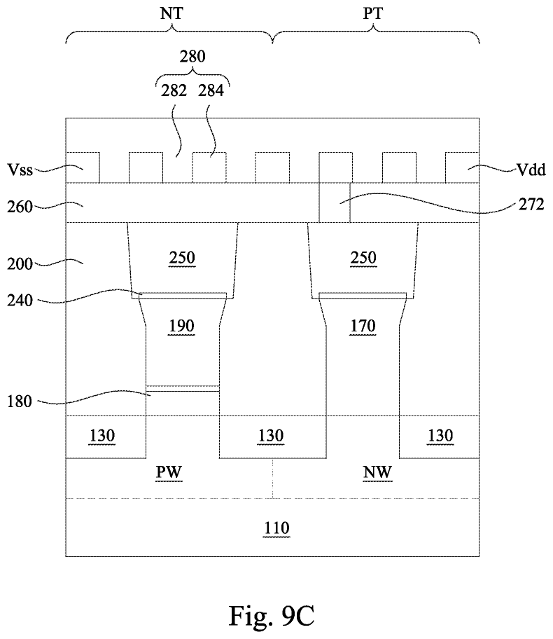

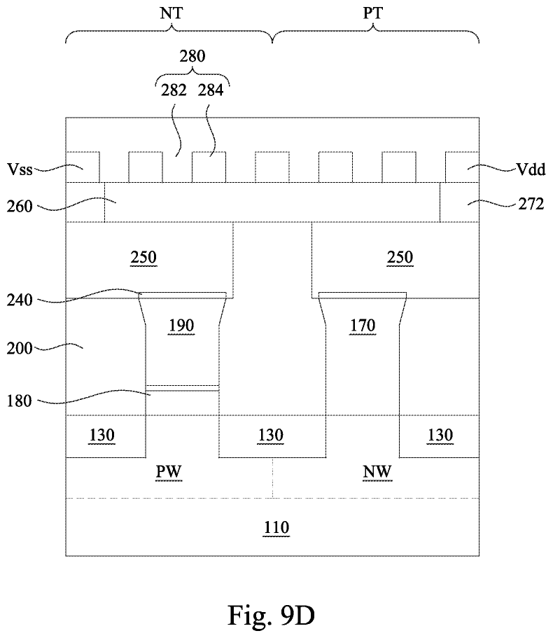

FIGS. 9A-9D are cross-sectional views of an integrated circuit device according to some embodiments of the present disclosure. FIG. 9A illustrate a cross-sectional view taken along the same line as the line X1-X1 in FIG. 8A. FIG. 9B illustrate a cross-sectional view taken along the same line as the line X2-X2 in FIG. 8A. FIG. 9C illustrate a cross-sectional view taken along the same line as the line Y2-Y2 in FIG. 8A. FIG. 9D illustrate a cross-sectional view taken along the same line as the line Y3-Y3 in FIG. 8A. Details of the present embodiments are similar to those of FIGS. 1-8F, except that air gaps AG are formed between the source/drain epitaxial structures 190 and the isolation layers 180 in the region NT. As aforementioned, in the region NT, with the isolation layer 180 covering the substrate 110, the epitaxial growth process may use gaseous and/or liquid precursors, which interact with the composition of semiconductor materials of the channel layers 124 in the region NT, thereby forming the source/drain epitaxial structures 190. In the present embodiments, the deposition parameters of the epitaxial growth process are controlled such that the bottom surface of the source/drain epitaxial structures 190 may be spaced apart from the isolation layer 180, not be in contact with the isolation layer 180. On the other hand, in the region PT, with no isolation layer 180 covering the substrate 110, the epitaxial growth process may use gaseous and/or liquid precursors, which interact with the composition of semiconductor materials of the channel layers 124 and the substrate 110 in the region PT, thereby forming the source/drain epitaxial structures 170. Other details of the present embodiments are similar to those mentioned above, and thereto not repeated herein.

FIGS. 10A and 10B are cross-sectional views of an integrated circuit device according to some embodiments of the present disclosure. Details of the present embodiments are similar to those of FIGS. 1-8F, except that an observable interface can be found between the epitaxial features ES and the substrate 110. The intrinsic epitaxial features ES are formed in the recesses R1 in the regions NT and PT, between the source/drain epitaxial structures 170/190 and the substrate 110. Other details of the present embodiments are similar to those mentioned above, and thereto not repeated herein.

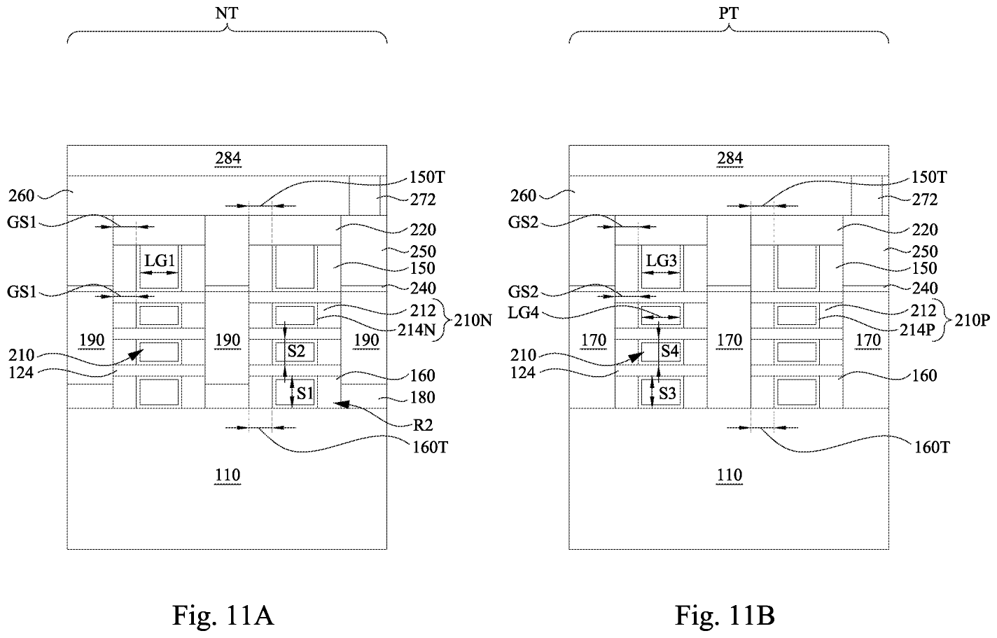

FIGS. 11A and 11B are cross-sectional views of an integrated circuit device according to some embodiments of the present disclosure. Details of the present embodiments are similar to those of FIGS. 1-8F, except that the etching time/duration of the lateral etching of the sacrificial layers 122 (referring to FIG. 4) is controlled such that the lateral depth of the lateral recesses R2 is less than the thickness 150T of the gate spacers 150, which in turn result in that the inner spacers 160 are formed with a thickness 160T substantially equal to the thickness 150T of the gate spacers 150. Stated differently, a difference between the thicknesses 160T and 150T is less than about 5% or 10% of the thickness 160T/150T.

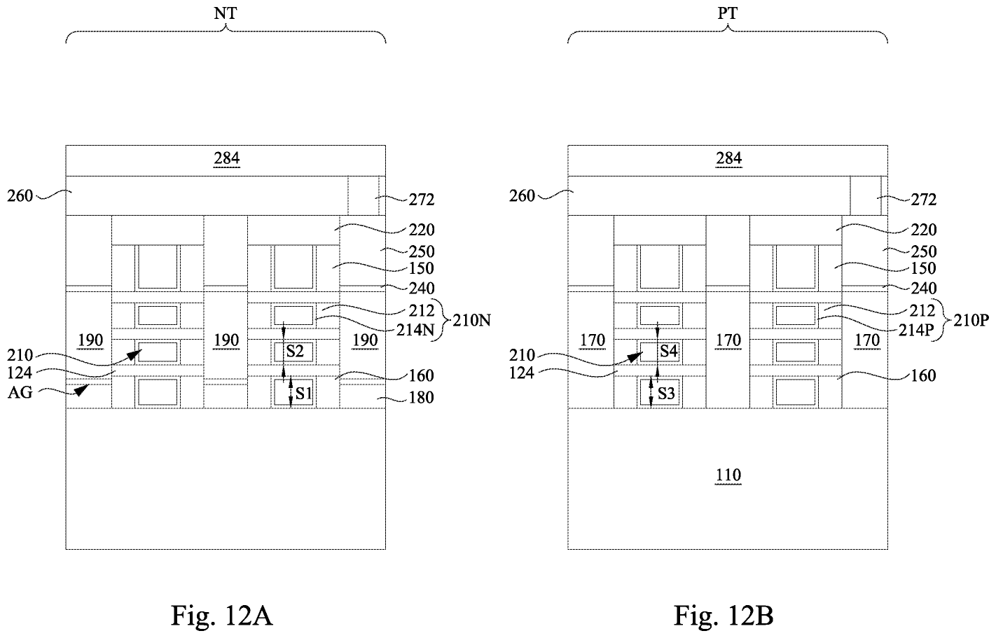

FIGS. 12A and 12B are cross-sectional views of an integrated circuit device according to some embodiments of the present disclosure. Details of the present embodiments are similar to those of FIGS. 11A and 11B, except that air gaps AG are formed between the source/drain epitaxial structures 190 and the isolation layers 180 in the region NT. The formation of the air gap AG is similar to those described in the embodiments of FIGS. 9A-9D. Other details of the present embodiments are similar to those mentioned above, and thereto not repeated herein.

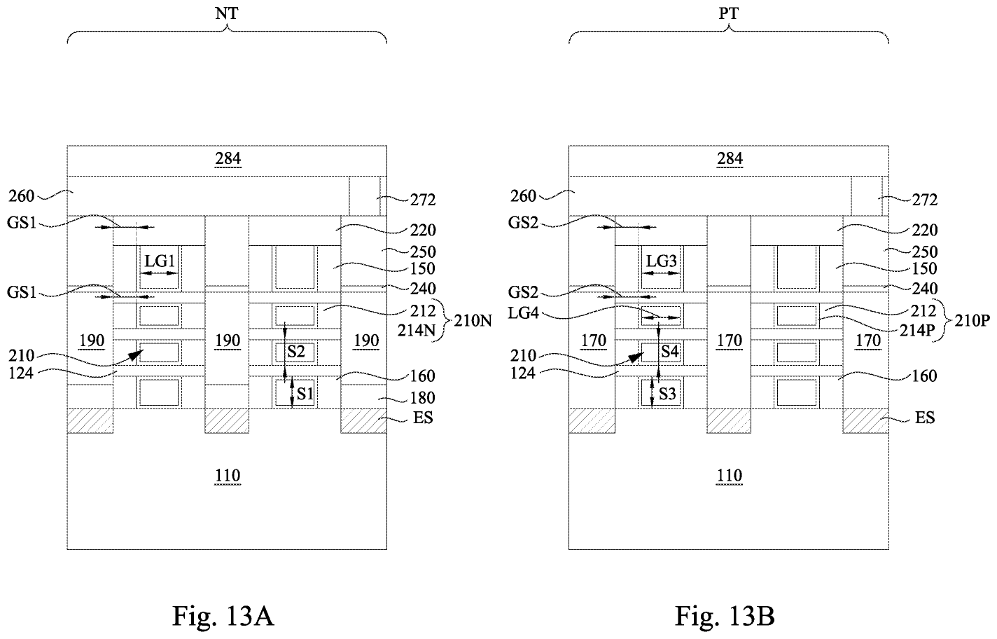

FIGS. 13A and 13B are cross-sectional views of an integrated circuit device according to some embodiments of the present disclosure. Details of the present embodiments are similar to those of FIGS. 11A and 11B, except that the intrinsic epitaxial features ES are formed in the recesses RI in the regions NT and PT, between the source/drain epitaxial structures 170/190 and the substrate 110. The formation of the intrinsic epitaxial features ES is similar to those described in the embodiments of FIGS. 10A and 10B. Other details of the present embodiments are similar to those mentioned above, and thereto not repeated herein.

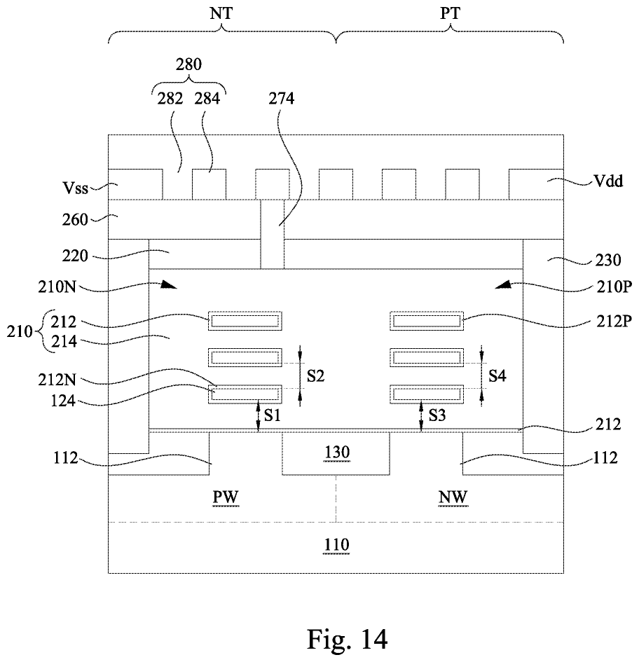

FIG. 14 is a cross-sectional view of an integrated circuit device according to some embodiments of the present disclosure. Details of the present embodiments are similar to those of FIGS. 1-8F, except that the gate structures 210N and 210P include a same gate metal layer 214 for NMOSFET and PMOSFET, respectively. In some embodiments, prior to the disposition of the gate metal layer 214, the underlying gate dielectric layer 212 in the region NT and PT (labelled as the dielectric layers 212N and 212P respectively) may be doped with suitable dopants (e.g., Lanthanum (La)) with different concentrations. After the disposition of the gate metal layer 214, dopants (e.g., La) with different concentrations in the underlying gate dielectric layer 212N and 212P may be diffused into the same gate metal layer 214, and therefore different work functions are provided for the high-k/metal gate structures 210N and 210P. Thus, the gate dielectric layer 212N and 212P may include the same material doped with different La concentrations. Other details of the present embodiments are similar to those mentioned above, and thereto not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that a gate structure is designed to be located between sheets with a narrower sheet-to-sheet distance and located between sheet and bottom Si with a wider sheet-to-bottom Si distance. The narrower sheet-to-sheet distance is advantageous for source/drain depth reduction, thereby lowering capacitance between gate and source/drain regions as well as lowering resistance for source/drain regions. The wider sheet-to-bottom Si distance is advantageous for manufacturing margin for forming the isolation layers and the source/drain sidewall inner spacers. Another advantage is that an isolation layer is located between the n-type source/drain epitaxial structures and the p-type well in the substrate, thereby reducing the capacitances between gate to source/drain regions and the junction capacitance between source/drain regions and well region. Still advantage is that NMSOFETs' S/D regions have an isolation layer for reducing the capacitances of gate to source/drain regions and leakage from source/drain regions to well region, and PMSOFETs' S/D regions extended into bulk-Si region to have more volume for SiGe strain (channel mobility) enlargement. Still advantage is that the scaling of the top gate width and the enlargement of the width of the top gate spacer is advantageous for capacitance reduction between source/drain contact and gate.

In some embodiments of the present disclosure, an integrated circuit (IC) device includes a first nanostructure, a second nanostructure, a first gate structure, a first source/drain epitaxial structure, and a dielectric isolation layer. The first nanostructure is spaced apart from a semiconductor substrate by a first spacing. The second nanostructure is above and spaced apart from the first nanostructure by a second spacing. The second spacing is less than the first spacing. The first gate structure surrounds the first nanostructure and the second nanostructure. The first source/drain epitaxial structure is adjacent to both the first nanostructure and the second nanostructure. The dielectric isolation layer is between the first source/drain epitaxial structure and the semiconductor substrate. A top surface of the dielectric isolation layer is higher than a top surface of the semiconductor substrate and lower than a bottom surface of the first nanostructure.

In some embodiments of the present disclosure, an integrated circuit (IC) device includes a first nanostructure, a second nanostructure, a gate structure, a source/drain epitaxial structure, a source/drain contact, a gate spacer, a first inner spacer, and a second inner spacer. The second nanostructure is above the first nanostructure. The gate structure surrounds the first and second nanostructures. The source/drain epitaxial structure is adjacent to the first and second nanostructures. The source/drain contact is over the source/drain epitaxial structure. The gate spacer spaces the source/drain contact from the gate structure. The first inner spacer is below the first nanostructure and spacing the source/drain epitaxial structure from the gate structure. The second inner spacer is between the first and second nanostructures and spacing the source/drain epitaxial structure from the gate structure. The first inner spacer has a width less than a width of the gate spacer and a height greater than a height of the second inner spacer.

In some embodiments of the present disclosure, a method for fabricating an integrated circuit (IC) device is provided. The method includes depositing an epitaxial stack over a semiconductor substrate, wherein the epitaxial stack comprises a first sacrificial layer, a first channel layer, a second sacrificial layer, and a second channel layer stacked in a sequence, wherein a thickness of the first sacrificial layer is greater than a thickness of the second sacrificial layer; patterning the epitaxial stack into at least a first fin; etching the first fin to expose sidewalls of the first channel layer, the first sacrificial layer, the second channel layer, and the second sacrificial layer in the first fin; forming a first inner spacer and a second inner spacer adjacent the sidewalls of the first sacrificial layer and the second sacrificial layer in the first fin, wherein a height of the first inner spacer is greater than a height of the second inner spacer; forming an isolation layer in contact with the first inner spacer; and forming a first source/drain epitaxial structure in contact with the sidewalls of the first channel layer and the second channel layer in the first fin.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a first nanostructure spaced apart from a semiconductor substrate by a first spacing;
a second nanostructure above and spaced apart from the first nanostructure by a second spacing, the second spacing being less than the first spacing;
a first gate structure surrounding the first nanostructure and the second nanostructure;
a first source/drain epitaxial structure adjacent to both the first nanostructure and the second nanostructure; and
a dielectric isolation layer between the first source/drain epitaxial structure and the semiconductor substrate, wherein a top surface of the dielectric isolation layer is higher than a top surface of the semiconductor substrate and lower than a bottom surface of the first nanostructure.

2. The IC device of claim 1, wherein a vertical distance between the top surface of the dielectric isolation layer and the bottom surface of the first nanostructure is less than the second spacing.

3. The IC device of claim 1, wherein a bottom surface of the first source/drain epitaxial structure is in contact with the top surface of the dielectric isolation layer.

4. The IC device of claim 1, wherein a bottom surface of the first source/drain epitaxial structure is spaced apart from the top surface of the dielectric isolation layer by an air gap.

5. The IC device of claim 4, wherein the bottom surface of the first source/drain epitaxial structure is lower than the bottom surface of the first nanostructure.

6. The IC device of claim 1, further comprising:
an intrinsic epitaxial feature between the dielectric isolation layer and the semiconductor substrate.

7. The IC device of claim 1, further comprising:
a third nanostructure spaced apart from the semiconductor substrate by a third spacing;
a fourth nanostructure above and spaced apart from the third nanostructure by a fourth spacing, the fourth spacing being less than the third spacing;
a second gate structure surrounding the third nanostructure and the fourth nanostructure; and
a second source/drain epitaxial structure adjacent to both the third nanostructure and the fourth nanostructure, wherein a bottom surface of the second source/drain epitaxial structure is lower than a bottom surface of the first source/drain epitaxial structure.

8. The IC device of claim 7, wherein the bottom surface of the second source/drain epitaxial structure is in contact with the semiconductor substrate.

9. The IC device of claim 7, further comprising:
an intrinsic epitaxial feature between the second source/drain epitaxial structure and the semiconductor substrate, wherein the bottom surface of the second source/drain epitaxial structure is in contact with the intrinsic epitaxial feature.

10. An integrated circuit (IC) device, comprising:
a first nanostructure;
a second nanostructure above the first nanostructure;
a gate structure surrounding the first and second nanostructures;
a source/drain epitaxial structure adjacent to the first and second nanostructures;
a source/drain contact over the source/drain epitaxial structure; a
a gate spacer spacing the source/drain contact from the gate structure;
a first inner spacer below the first nanostructure and spacing the source/drain epitaxial structure from the gate structure; and
a second inner spacer between the first and second nanostructures and spacing the source/drain epitaxial structure from the gate structure, wherein the first inner spacer has a width less than a width of the gate spacer and a height greater than a height of the second inner spacer.

11. The IC device of claim 10, wherein the second inner spacer has a width less than the width of the gate spacer.

12. The IC device of claim 10, wherein the first and second inner spacers comprise a material different from that of the gate spacer.

13. The IC device of claim 10, wherein a k value of the first and second inner spacers is lower than a k value of the gate spacer.

14. The IC device of claim 10, wherein a width of an upper portion of the gate structure adjoining the gate spacer is greater than a width of a lower portion of the gate structure adjoining the first inner spacer.

15. The IC device of claim 10, further comprising:
a dielectric isolation layer below the source/drain epitaxial structure and in contact with the first inner spacer.

16. A method for fabricating an integrated circuit (IC) device, comprising:
depositing an epitaxial stack over a semiconductor substrate, wherein the epitaxial stack comprises a first sacrificial layer, a first channel layer, a second sacrificial layer, and a second channel layer stacked in a sequence, wherein a thickness of the first sacrificial layer is greater than a thickness of the second sacrificial layer;
patterning the epitaxial stack into at least a first fin;
etching the first fin to expose sidewalls of the first channel layer, the first sacrificial layer, the second channel layer, and the second sacrificial layer in the first fin;
forming a first inner spacer and a second inner spacer adjacent the sidewalls of the first sacrificial layer and the second sacrificial layer in the first fin, wherein a height of the first inner spacer is greater than a height of the second inner spacer;
forming an isolation layer in contact with the first inner spacer; and
forming a first source/drain epitaxial structure in contact with the sidewalls of the first channel layer and the second channel layer in the first fin.

17. The method of claim 16, wherein the epitaxial stack is patterned into the first fin and a second fin, the method further comprises:
etching a second fin to expose sidewalls of the first channel layer, the first sacrificial layer, the second channel layer, and the second sacrificial layer in the second fin; and
forming a second source/drain epitaxial structure in contact with the sidewalls of the first channel layer and the second channel layer in the second fin, wherein a bottom of the second source/drain epitaxial structure is lower than a bottom of the first source/drain epitaxial structure.

18. The method of claim 17, further comprising:
forming a third inner spacer and a fourth inner spacer adjacent the sidewalls of the first sacrificial layer and the second sacrificial layer in the first fin, wherein a height of the third inner spacer is greater than a height of the fourth inner spacer, and forming the isolation layer is performed such that the third inner spacer is free of contacting a material of the isolation layer.

19. The method of claim 16, further comprising:
forming a gate structure over the first fin; and
forming a gate spacer alongside the gate structure prior to etching the first fin, wherein a thickness of the gate spacer is greater than a thickness of the first inner spacer and the second inner spacer.

20. The method of claim 19, further comprising:
laterally recessing the sidewalls of the first sacrificial layer and the second sacrificial layer prior to forming the first inner spacer and the second inner spacer, wherein the first sacrificial layer and the second sacrificial layer extend beyond a sidewall of the gate spacer after laterally recessing.
